(19) United States
(12) Patent Application Publication
(10) Pub. No.: US 2009/0261312 A1
(43) Pub. Date: Oct. 22, 2009

(54) INTEGRATED CIRCUIT INCLUDING AN ARRAY OF LOW RESISTIVE VERTICAL DIODES AND METHOD

(75) Inventor: Ulrike Gruening-von Schwerin, Muenchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: Qimonda AG, Muenchen (DE)

(21) Appl. No.: 12/105,867

(22) Filed: Apr. 18, 2008

(51) Int. Cl. H01L 47/00; H01L 21/82; H01L 21/00

(52) U.S. Cl. 257/2; 257/202; 438/128; 438/510; 257/E47.001; 257/E21.602; 257/E21.001

(57) ABSTRACT

An integrated circuit including an array of low resistive vertical diodes and method. One embodiment provides an array of diodes at least partially formed in a substrate for selecting one of a plurality of memory cells. A diode is coupled to a word line. The word line includes a straight-lined portion and protrusions. The diode includes an active area located between two adjacent protrusions.

### BACKGROUND

The invention relates to an integrated circuit including an array of vertical diodes to select one of a plurality of resistively switching memory cells and a method for forming the integrated circuit.

In resistively switching memory cells, for example, phase change random access memory (PCRAM), the information is stored in a volume of switching active material, wherein the switching active material may switch between two states. In a first state the switching active material may have a high resistivity, i.e. a low conductivity, and a lesser resistivity, i.e. a higher conductivity, in a second state. Accordingly, the information of a bit may be assigned to a PCRAM cell, wherein the state of the cell reflects the status of the bit. Although the invention is described for PCRAM cells in the following the structure and methods can be used for any random access memory including diodes as selection means.

For reading a resistively switching memory cell the state of the volume of phase change material is sensed, i.e. the conductivity is sensed. This can be achieved for example by applying a predefined voltage to the cell and sensing the amplitude of the current flowing through the cell. For switching the state of a resistively switching memory cell a high current is sent through the volume of switching active material in order to heat and subsequently change the material from a one state to the other. A selection diode comprised in the cell thus should be able to send a strong current through the cell.

To be cost competitive, a small cell size and a cost competitive process is required for a memory product including resistively switching memory cells. In conventional architectures a 1D 1R assignment is used, i.e. one diode (D) for selecting one resistively switching memory element (R) from a plurality of memory elements.

### SUMMARY

According to one embodiment a structure and a manufacturing method for an integrated circuit including an array of diodes is provided. A diode is coupled to a word line, wherein the word line includes a straight-lined portion and protrusions, an wherein the diode includes an active area located between two adjacent protrusions.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates a schematic circuit diagram of an integrated circuit including two memory cells representing an array of several memory cells.

FIGS. 2a, 2b, 2c illustrate a schematic top-down view onto a cutout of a layout of an array of memory cells and cross sectional views.

FIGS. 3a, 3b, 3c illustrate a top-down view on and cross sectional views through an array of diodes in an early processing stage.

FIGS. 4a, 4b, 4c illustrate a top-down view on and cross sectional views through the chip after etching word line trenches.

FIGS. 5a, 5b, 5c illustrate a top-down view on and cross sectional views through the chip after forming a single-sided insulator in word line trenches.

FIGS. 5a, 5b, 5c illustrate a top-down view on and cross sectional views through the chip before forming the word lines.

FIGS. 6a, 6b, 6c illustrate a top-down view on and cross sectional views through the chip after forming the word lines.

FIGS. 7a, 7b, 7c illustrate a top-down view on and cross sectional views through the chip after forming the word lines and diodes.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

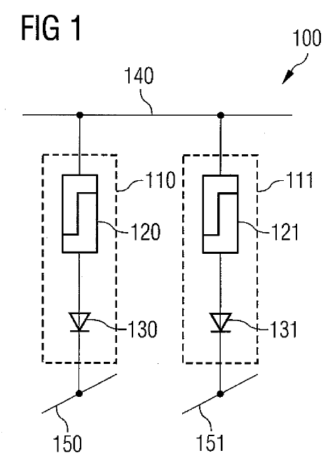

The electrical circuit 100 illustrated in FIG. 1 includes a first and a second memory cell 110, 111 exemplifying a plurality of identical memory cells arranged in an array of memory cells, for example, in an integrated circuit including phase change random access memory (PCRAM). Each cell includes a volume of switching active material 120, 121, i.e. a resistively switching memory element, and a diode 130, 131 for selecting the memory element from the plurality of memory elements. The memory elements are coupled to bit line 140 and to an associated diode, which in turn is coupled to a word line 150, 151. In the direction of a bit line a plurality of memory cells is coupled to one bit line, wherein each memory cell is coupled to a different word line. Vice versa in the direction of a word line a plurality of memory cells is coupled to one word line, and wherein each cell is coupled with its residual contact to a different bit line.

An individual memory cell 110 is thus coupled to an individual pair of one word line 150 and one bit line 140 and may be selected by selecting the associated pair of word and bit line. For operating a cell the voltage of the associated bit line is raised until the diode reaches the conducting state, such that a current flows from the bit line through the memory element and the diode to the word line, which dissipates the current. It is apparent that the direction of the diode and thus the direction of the current flow may easily be inversed by exchanging the P+ and the N doped regions of the diode, and the applied voltages.

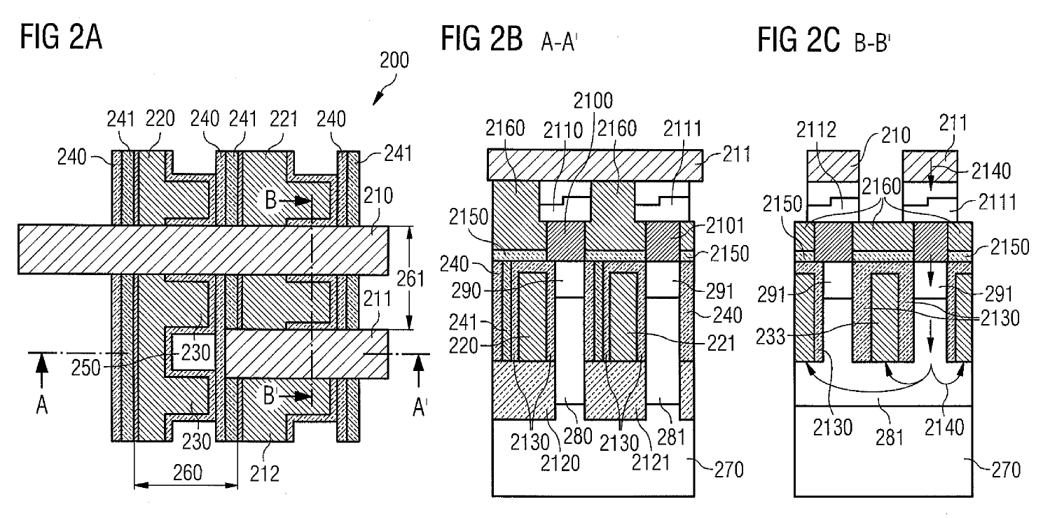

FIGS. 2a, 2b and 2c illustrate the structure of an array of memory cells, wherein each cell includes a volume of resistively switching material and an associated diode. FIG. 2a illustrates a top-down view onto a cutout of a layout of an array 200 of memory cells, FIG. 2b illustrates a cross sectional view along cut line A-A′, which is parallel to and through a bit line, and FIG. 2c illustrates a cross sectional view along cut line B-B′ being parallel to and through a word line.

In this drawing the insulation material separating and insulating adjacent elements is partly omitted for reasons of clearness. It is apparent to those skilled in the art that elements, for example such as bit lines or intersecting word lines, are embedded in a suitable dielectric to galvanically insulate these from each other. Furthermore some elements, which are comprised in a resistively switching memory cell, for example, such as volumes of resistively switching material or the N doped region of the diodes, are not illustrated, as they are hidden by other elements located above them.

Bit lines 210, 211 are the top most elements in FIG. 2a, wherein bit line 211 is discontinued in order to illustrate details below. Memory elements, i.e. volumes of resistively switching material, and corresponding bottom electrode contacts are also omitted to illustrate the architecture below these elements.

Word lines 220 and 221 are arranged below and perpendicular to the bit lines. In the illustrated embodiment the word lines may be buried below the surface of the substrate, such that they form buried word lines, wherein an insulating layer on top of the word lines is not illustrated in this figure. As illustrated the word lines are not shaped as flat, plane lines. Instead they have a comb like shape, wherein the teeth or protrusions of word line 220 are in a direction parallel to the surface of the substrate. Protrusions 230, 231 of word line 220 are directed to adjacent word line 221 and are insulated from adjacent word line 221 by insulating dielectric layers 240, 241.

Word line 220 and its protrusions respectively surround an active area 250 of a diode at three of its four sides, the fourth side being insulated by dielectrics 240, 241 from adjacent word line 221.

Even though the figure is not drawn to scale arrows 260, 261 indicate the minimal dimensions of a cell. The periodicity of word lines 220, 221 is given to 2 F as indicated by arrow 260 and the periodicity of bit lines 210-211 also is given to 2 F, confer arrow 261, wherein F denotes the minimum feature size defined by the manufacturing method used. Consequently the minimal size of the illustrated memory cell is around 4 F².

Also the approximate size of an active area is defined by the periodicity of the bit—and the word lines. According to current production capabilities a width of 1 F is required for a bit- or a word line, thus the area of an active area is approximately 1 F by 1 F resulting in an area of 1 F². Advances in the art of metallurgy and lithography, among others, may change these relative dimensions.

The vertical structure of the arrangement is illustrated more precisely in FIG. 2b, which is a cross sectional view along cut line A-A′ through two memory cells formed in substrate 270. N doped region 280 and P+ doped region 290 form a diode connected via bottom electrode contact 2100 to memory element 2110, i.e. a volume of resistively switching material, which in turn is coupled to bit line 211. Analogously N doped region 281, P+ doped region 291 form the diode of an adjacent memory cell, which includes memory element 2111 coupled via bottom electrode contact 2101 to bit line 211.

An insulation trench 2120 and 2121 respectively is arranged below the straight-lined portion of the word line trenches. Insulation 2120, 2121 extends deeper into substrate 270 than the N doped regions 280, 281 in order to separate these from each other, thus separating a row of diodes coupled to a first word line from diodes coupled to adjacent word lines.

Reference numeral 2150 denotes a mid-of-line layer of any suitable insulating material, e.g., silicon nitride, and numeral 2160 denotes any insulating material, e.g., silicon oxide, which both electrically separate adjacent elements of the structure.

FIG. 2c illustrates a cross sectional view along cut line B-B′ running parallel to the word lines and through protrusions of word line 221 and active areas formed by N doped region 280 and P+ doped regions 290, 291 respectively. The P+ doped regions and the N doped regions are insulated by insulation spacers 2130 applied to the vertical sidewalls of the word lines, i.e. both the straight-lined portion and the protrusions of a word line. Insulation 2120, 2121 is arranged below the straight portion, but not below a protrusion of a word line, such that the bottoms of the protrusions of word line 211 connect to the N doped regions of the diodes. In this way the N doped regions of diodes are galvanically coupled to word lines, in one embodiment an N doped region of a diode is galvanically coupled to the bottom of the protrusions of a word line.

For reading, i.e. for sensing the resistivity of the memory element, a comparatively small current is sent through the memory element, and the current and/or the voltage applied to the memory element are sensed in an appropriate, peripheral sensing circuitry. For writing a memory cell, i.e. heating the material of the memory element, a strong current pulse is sent through the memory element. As in either case the direction of the current flow is identical, the voltage between a selected bit line 211 and a word line 221 is raised to cause a current from the bit line through the memory cell to the word line. Arrows 2140 exemplify a current flowing from bit line 211 through a memory cell to a word line 221. The current starts from bit line 211, passes the volume of switching active material 2111, for example phase change material forming the memory element, and leaves the memory element via bottom electrode contact 2101 to enter the P+ doped region 291. The current then flows through the N doped region 281 into protrusions of word line 221. Although most of the current will leave the N doped region via the closest protrusions, i.e. the protrusions adjacent to the particular diode, smaller portions of the current will leave the N doped region via protrusions located farther away from the diode. However the current is discharged via word line 221 only, i.e. the current will not spread to other word lines, because the doped region of the diode is separated from other word lines by the insulation 2120, 2121 extending below the straight portion of the word lines

The structure in this way provides an array of memory cells, wherein each memory cell includes a resistively switching memory element and a diode for selecting the cell. The P+ doped and N doped regions of the diode are arranged such that the current flows vertically through the diode with respect to the surface of the original substrate, in which the diode regions are formed. In the direction of the current flow the diode substantially may have a cross sectional area of a substantially quadrangular or rounded island shape. The diode is surrounded by a word line or its protrusions at three sides. One of the doped diode regions is galvanically coupled to the two protrusions located at opposite sides of the diode; in one embodiment the diode region is coupled at the bottom side of the protrusions to a word line.

While in this embodiment the diode is illustrated with the P+ doped region above the N doped region it is apparent to those skilled in the art that the direction of the diode may be inverted by interchanging the location of the doped regions. Accordingly, when operating the cells including an inverted diode the current will flow from the word line to the bit line.

In the following a production method for manufacturing a structure as illustrated in FIGS. 2a-2c is described.

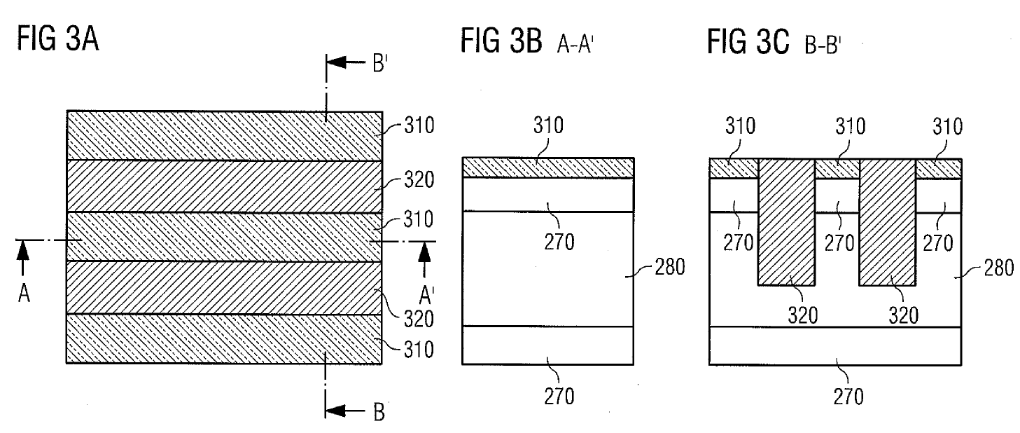

FIGS. 3a, 3b and 3c illustrate views of the memory device in an early manufacturing stage, wherein FIG. 3a is a top view on the chip, FIG. 3b illustrates a cross sectional view along cut line A-A′, and FIG. 3c illustrates a cross sectional view along cut line B-B′.

In a first process, a well doping is performed by forming a N doped tray 280 is formed in a conventional weakly p-doped substrate 270, for example, by deep implanting N ions into the substrate, wherein a p-doped layer of substrate 270 may be maintained at the surface of the substrate. In one embodiment the dopant may be implanted to have a peak concentration beneath the bottom of the word line protrusions, which will couple to the diodes. The N doped tray will be shaped to N doped diode regions in further processes. Also, the substrate 270 may have a suitable p-doping for cell-to-cell insulation.

Note that in one embodiment processing of doping the substrate may be performed at any later process when the appropriate areas are accessible to implant ions into the substrate.

Then a hardmask layer 310, i.e. a nitride, and a photoresist, is deposited on the surface of the chip and further processed by conventional photolithography into lines. Then auxiliary trenches are etched into the doped substrate 280, which are subsequently filled with a sacrificial insulating material 320 using a conventional method for depositing the material. The sacrificial material may be one of SiO2 or Al2O3 or SiGe. In the described example the sacrificial material may/can be SiGe.

After the sacrificial material 320 has been deposited, it is planarized to the surface of the hardmask 310 for example by a chemical-mechanical planarization (CMP) method as preparation for subsequent processes.

FIG. 3a illustrates a top-view on the chip depicting alternating lines of hardmask material 310 and sacrificial material 320. The cross section illustrated in FIG. 3b illustrates the N doped tray 280 sandwiched between substrate 270. FIG. 3c, i.e. the cross sectional view along B-B′ illustrates the auxiliary trenches filled with sacrificial material 320, which extend into the N doped tray 280.

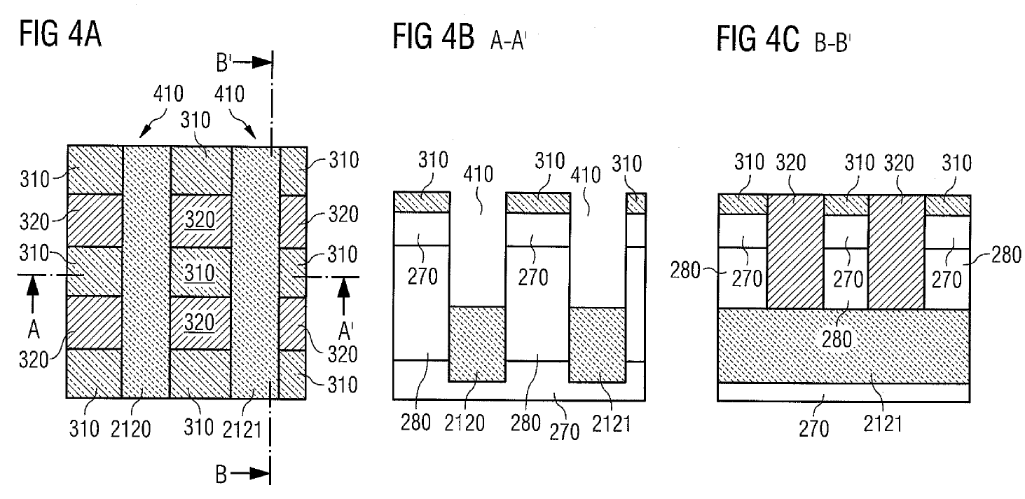

FIGS. 4a, 4b and 4c illustrate the views as in FIG. 3 after having performed further processes.

In a next process word line trenches 410 perpendicular to the auxiliary trenches filled with sacrificial material 320 are etched. This can be done, for example, by depositing a suitable mask material, i.e. a doped oxide or nitride, and a photoresist, shaping the photoresist material by conventional lithographic processes into lines and performing conventional etching steps to etch word line trenches 410 through mask material 310, through the substrate 270, 280 of the chip and through the sacrificial material 320. The word line trenches 410 extend through the N doped substrate 280 into the substrate 270. Subsequently the word line trenches 410, i.e. the substrate material 270 and 280, optionally may be oxidized, such that the substrate material of the vertical sidewalls and the bottom of the word line trenches forms a thin insulating layer, which is not illustrated in the figures.

The lower portion of the word line trenches 410 is then filled with an insulating material 2120 and 2121, for example such as silicon dioxide SiO2. This can be achieved by filling the word line trenches 410 with the insulating material, then planarizing the surface of the chip and recessing the material 2120, 2121 for example by a recess etch, wherein the etching process is preferentially stopped within the region 280. In this way the insulation below the straight portion of the word lines separates the N doped regions of one row of diodes associated with a first word line from the N doped diode regions associated with an adjacent word line. With regard to the top of insulating material 2120 can be below or above the bottom of the trench filled with sacrificial material 320.

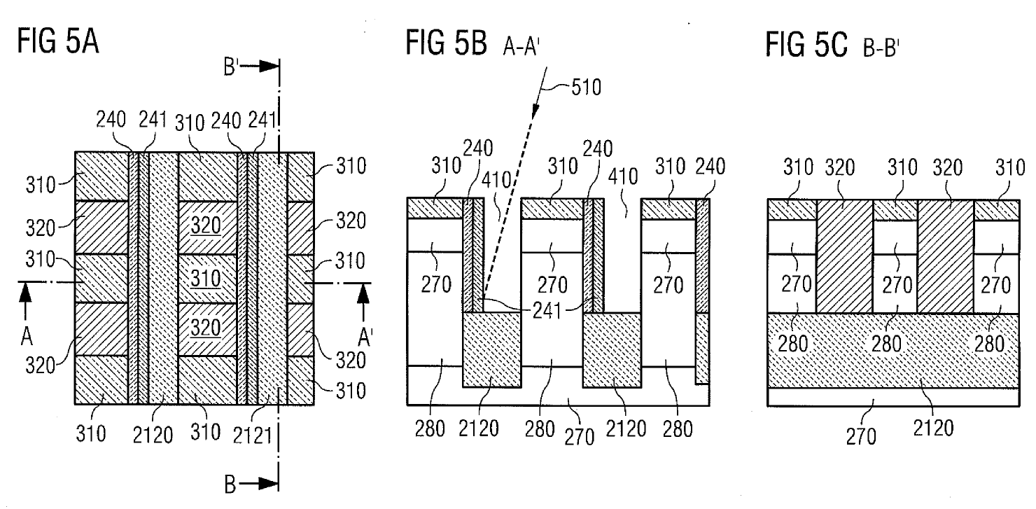

FIGS. 5a, 5b and 5c illustrate the views as in FIG. 4 after having formed a single-sided word line isolation 240 covered by a layer of insulating silicon oxide 241.

In order to form a single sided insulation layer 240 in the straight-lined portion of the word line trenches 410 that is an insulation layer at one sidewall of the word line trenches, a liner of suitable insulating material, for example, such as silicon nitride, is deposited on the chip. This nitride liner 240 must then be processed in order to cover only one sidewall of a word line trench 410. For this purpose a layer of undoped polycrystalline or amorphous silicon 241 is deposited on the chip, which covers the nitride liner 240. Subsequently an angled boron (BF2) implant is performed with an angle as indicated by arrow 510, wherein the angle is adjusted such that at least the undoped poly silicon on one vertical sidewall in the word line trench is boron implanted. The implantation angle may be varied such that also the polysilicon on the bottom of the word line trenches is implanted partially or fully, but wherein the polysilicon on the other sidewall of the word line trench remains undoped. In this way the polysilicon layer is P+ doped on the horizontal surface of the chip and at least on one sidewall in the word line trench 410, optionally the polysilicon located on the horizontal bottom of the word line trenches may also be P+ doped with boron. That is, depending on the chosen implantation conditions the dopant may be backscattered, which will also result in implantation of the silicon 241 at the bottom of the word line trench 410, wherein the amount of dopant implanted into the silicon 241 may be higher close to the doped vertical sidewall and may decrease farther away. As will become apparent in the following description, the subsequent etching process may partially remove the silicon. Note that for the function of the architecture it is of minor importance whether the silicon and the liner are removed from the bottom of the word line trenches, as these layers add insulating layers to the anyway insulating material 2120, 2121.

The polysilicon located at one sidewall remains undoped. Subsequently the undoped polysilicon is etched selectively to the doped polysilicon thus removing the undoped polysilicon from one sidewall of the word line 410, thus baring the nitride liner located at the one sidewall under the polysilicon.

The remaining P+ doped polysilicon can then be oxidized optionally, such that it changes from conducting to insulating.

Then the silicon nitride liner is removed selectively to the P doped or oxidized poly silicon, where accessible. That is, the nitride liner is removed from the one vertical sidewall of the word line trenches, such that the nitride liner on the one sidewall of the word line trench is removed from the sacrificial material 320, the substrate 270 and the N doped substrate 280 as illustrated in FIG. 5c.

Afterwards, a spacer etch is optionally performed to remove layer 240 and 241 from the top surface and optionally also partially from the trench bottoms. This removal bares the top surface of sacrificial material 320.

In an alternate way to produce the single-sided wordline trench isolation, a photolithographic process is added after filling the wordline trenches 410 with insulating material 2120 and 2121, the line pattern being offset to the wordline trenches in a way, that the insulating layer 2120 can be removed inside the wordline trenches selectively to 310 to a predetermined depth, such that the insulating layer is removed at one sidewall of the wordline trenches 410 and remains along the opposite sidewall.

Within the scope of the invention, all processes suitable in creating a single-sided sidewall insulation in the wordline trenches can be applied.

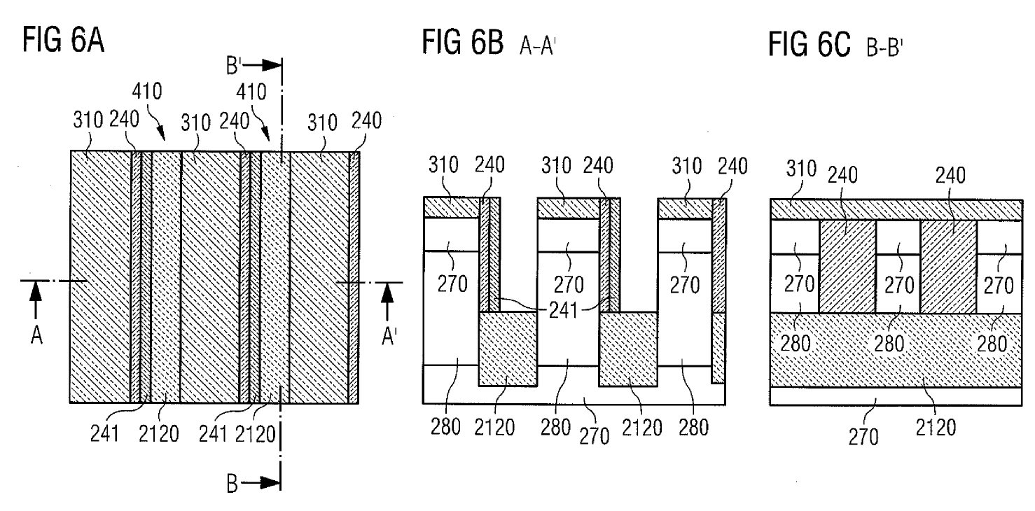

FIGS. 6a, 6b and 6c illustrate the top-down view and the cross-sectional views along cut lines A-A′ and B-B′ after removing the P+ doped polysilicon 241, the silicon nitride liner 240 and the hardmask layer 420 from the top surface of the chip and after removing the sacrificial material 320.

The blocks of sacrificial material 320 are removed, for example by wet or dry etching selective to the Si and the insulation layer 240. Removing the blocks of sacrificial material forms protrusions of the word line trench, such that the word line trenches get the comb like (comb-like) shape.

The shape of the word lines is then composed of the word line trenches 410 plus the areas formerly covered by the sacrificial material. Since the sacrificial material was removed, the underlying N doped substrate is visible in the top view. These areas form the protrusions of the word line trenches. Accordingly a word line includes a straight-lined portion and protrusions directed parallel to the substrate surface, such that a word line has a comb-like shape.

The top-view illustrates that a pillar of substrate 270, which in its lower portion is N doped, in one embodiment may have a substantially quadrangular base area. In alternative embodiments the base area of a pillar may be shaped more round or as a round island at all.

Irrespective of its base area shape a pillar on one side adjoins the straight-lined portion of a word line and on the opposite side is bordered by the insulating liner 240 as illustrated in the cross sectional views along cut line A-A′ and B-B′.

As in this processing stage the bottom of the protrusions of a word line trench is accessible, implants for doping the portions of a word line trench can be performed. That is, in case the N doped tray 280 was not produced in the very beginning, then the doping may be performed in this processing stage. Preferentially, the bottom of the trenches will be highly n-doped to improve contact resistance.

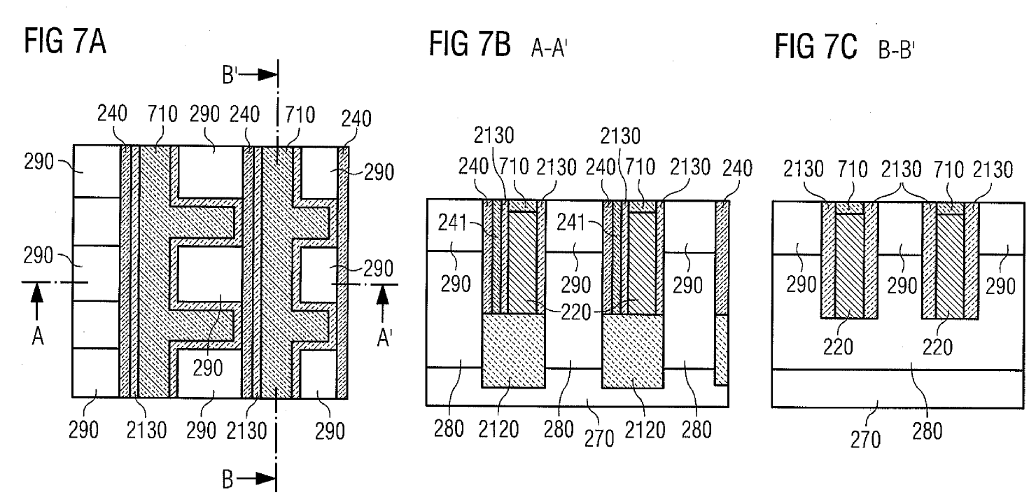

FIGS. 7a, 7b and 7c illustrate the top view and the cross sectional views as before, but after producing insulating spacers at the sidewalls of the word line trench including its protrusions and forming an intermediate word line in the word line trench, which is covered by an insulating cap. Also, the hardmask covering the active areas is removed and the top portions of the diode can be implanted.

The insulating spacers at the sidewalls of the word line trench can be produced from any suitable dielectric, i.e. insulating, material, for example, such as silicon oxide or nitride. The insulating material can be formed by deposition or oxidation as a layer at least on the substrate portions of the chip and is then etched anisotropically, for example, by an anisotropic reactive ion etching (RIE) process, to remove the material from horizontal surfaces while maintaining the material on vertical surfaces, thus forming insulating spacers 2130 covering the vertical sidewalls of a word line trench.

According to one embodiment a conducting word line material, for example a metal such as tungsten or a metal-containing conductor such as a metal silicide (TiSi, WSi) or nitride like TiN or conducting polysilicon, or a combination thereof is subsequently deposited on the chip to fill the residual word line trenches and to form word lines 220. The word line material is then etched back below the surface of the substrate. A cap 710 of insulating material is then produced for example by depositing a suitable insulating material, for example silicon oxide. The deposited layer may then be planarized to the wafer surface by a CMP process to prepare the chip for subsequent processing. In this way the word lines 220 are buried below the surface plane of the original substrate of the chip.

In one embodiment, not illustrated, a conventional word line stack can be produced as word lines, wherein the stack includes at least two layers of conducting material, for example, one layer of doped polysilicon and a metal, e.g., tungsten. The first layer of conducting material may be placed in the word line trenches after the insulating spacers have been produced, wherein the first layer at least extends to the ridge of a word line trench. The second layer of conducting material may then be placed on top of the first layer, extending above the silicon substrate, such that they are galvanically coupled, wherein the second layer may be shaped to lines, i.e. without protrusions, wherein these lines are arranged on top of the straight portion of the word lines. As the second layer of conducting material may have a higher conductivity than the first material it may improve the conductivity of a word line.

Subsequently the remainder of the hardmask 310 is removed, and the upper region of the substrate pillars is P+ implanted to form P+ doped diode regions 290. As the lower regions of the pillars are N doped a PN doping profile is produced in the pillars, the pillars thus becoming diodes. In one embodiment, the regions 290 and parts of 280 can also be produced by epitaxial growth. In this case one or more dielectric layers are deposited after removal of hardmask 310, and contact openings are formed through the dielectric to the top surface of region 280. Then epitaxial silicon is grown in the contact hole to form the upper part 290 of the diode.

The top-down view of FIG. 7a illustrates the structure of the word lines 220 covered by the insulating cap 710. Protrusions of the word lines 220 are directed in a direction parallel to the surface plane, wherein an area 290, i.e. a P+ doped region of a diode, is arranged between two adjacent protrusions of a word line 220. A word line 220 thus surrounds a diode at three of its sides, wherein protrusions of a word line adjoin a diode at two opposite sides, and the third side of a diode adjoins the straight portion of a word line. The fourth side of a diode is bordered by insulating liner 240, which insulates the diode from an adjacent word line in this way.

Cross-sectional view 7b illustrates that the word line material 220 in the straight portion of a word line is electrically isolated from the N doped material 280, whereas the protrusions of a word line, as illustrated in FIG. 7c, are electrically coupled to the N doped material 280. In this way a diode is galvanically coupled with its N doped region to the two adjoining protrusions of a word line 220.

The following description refers to FIG. 2 and relates to the manufacturing of the memory elements coupled to the diodes.

Once the array of diodes is formed in the substrate of the chip the memory elements are produced, which couple to P+ doped regions of the diodes. This can be achieved by depositing a middle-of-line (MOL) liner 2150, for example a comparatively thin liner of silicon nitride, and a comparatively thick layer of insulating material 2160, e.g., silicon oxide, on the chip. Both layers can be deposited by using conventional processes, for example, such as chemical vapor deposition (CVD). Then contact holes are etched through the layers by using conventional processes, wherein the holes bare the top surface of P+ doped diode regions. The contact holes are then filled with a suitable conducting material, for example, a metal such as tungsten, to form bottom electrode contacts 2100 and 2101, which will connect the diodes to the volumes of switching active material. Subsequently the volumes of switching active material 2110, 2111 are produced, for example, by depositing a layer of switching active material and shaping this layer into dedicated volumes coupled to the bottom electrode contacts 2100, 2101. The interspace between the volumes of switching active material is filled with a suitable dielectric 2160, for example, silicon oxide. Then bit lines 210, 211, which couple to the upper end of the volumes of switching active material 2110, 2111, are produced on top of the interspace dielectric 2160. The bit lines 210, 211 are arranged perpendicular to the word lines. The memory cells may then be accessed by selecting an associated pair of one word line and one bit line.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit comprising:
an array of diodes at least partially formed in a substrate for selecting one of a plurality of memory cells;
wherein a diode is coupled to a word line, the word line comprising a straight-lined portion and protrusions; and
wherein the diode comprises an active area located between two adjacent protrusions.

2. The integrated circuit of claim 1, comprising wherein the diode comprises a first doped region adjoining a second doped region of opposite conductivity type, and wherein the first doped region and the second doped region with respect to the surface of the substrate are arranged vertically above another.

3. The integrated circuit of claim 2, comprising wherein the first doped region is P+ doped and the second doped region is N doped.

4. The integrated circuit of claim 2, comprising wherein the top of the word lines is located beneath the upper doped region.

5. The integrated circuit of claim 1, comprising wherein the diode is coupled to two adjacent protrusions of the word line.

6. The integrated circuit of claim 5, comprising wherein the diode is coupled to the bottom sides of the two protrusions.

7. The integrated circuit of claim 1, comprising wherein the protrusions of a word line extend vertically deeper into the substrate than the straight-lined portion of the word line.

8. The integrated circuit of claim 1, comprising wherein the word lines are buried below the surface level of the original substrate of the chip.

9. The integrated circuit of claim 1, comprising wherein the word lines are formed as a stack of at least two conducting materials.

10. The integrated circuit of claim 1, comprising wherein the protrusions are directed parallel to the substrate surface, the word line and the protrusions thus forming a comb-like shape.

11. An integrated circuit comprising:
an array of diodes at least partially formed in a substrate for selecting one of a plurality of memory cells;
wherein a diode is coupled to a word line, the word line comprising a straight-lined portion and protrusions; and
wherein the diode comprises an active area located between two adjacent protrusions; and
a diode coupled to a volume of resistively switching material.

12. The integrated circuit of claim 11, comprising wherein the volume of resistively switching material is a phase change material.

13. A method of forming an integrated circuit comprising an array of diodes in a substrate for selecting one of a plurality of memory cells, comprising:
forming a first doped diode region in the substrate;
forming a plurality of auxiliary trenches in the substrate and filling the auxiliary trenches with a sacrificial material;
forming a plurality of word line trenches intersecting the filled auxiliary trenches, wherein the sacrificial material in the auxiliary trenches is removed at intersections of auxiliary trenches and word line trenches;
forming an insulating liner at one sidewall of the word line trenches;
removing the sacrificial material from the auxiliary trenches, the auxiliary trenches thus forming protrusions of the word line trenches;
forming word lines in the word line trenches and their protrusions; and
forming second doped diode regions in the substrate material located above the first doped diode regions.

14. The method of claim 13, wherein forming of the first doped diode region in the substrate comprises deep implanting a dopant into the substrate with a peak beneath the bottom of the word line protrusions.

15. The method of claim 14, comprising wherein the dopant is of N doping species.

16. The method of claim 13, comprising extending the word line trenches through the first doped diode region into the underlying substrate.

17. The method of claim 16, wherein forming word lines comprises filling a lower portion of the word line trenches with an insulating material.

18. The method of claim 13, wherein forming word lines comprises forming insulating spacers covering the vertical sidewalls of the word line trenches.

19. The method of claim 13, wherein forming the first doped diode region in the substrate comprises deep implanting ions into the substrate while maintaining a substrate layer above the first doped diode region.

20. The method of claim 22, comprising wherein the dopant is a N-doping species.

21. The method of claim 13, wherein forming the second doped diode regions comprises doping the substrate located above the first doped diode regions.

22. A method comprising:
forming a first doped diode region in the substrate;
forming a plurality of auxiliary trenches in the substrate and filling the auxiliary trenches with a sacrificial material;
forming a plurality of word line trenches intersecting the filled auxiliary trenches, wherein the sacrificial material in the auxiliary trenches is removed at intersections of auxiliary trenches and word line trenches;
forming an insulating liner at one sidewall of the word line trenches;
removing the sacrificial material from the auxiliary trenches, the auxiliary trenches thus forming protrusions of the word line trenches;
forming word lines in the word line trenches and their protrusions; and
forming second doped diode regions in the substrate material located above the first doped diode regions;
wherein forming an insulation liner at one sidewall of the word line trenches comprises:
depositing the insulation liner on the substrate;
depositing a layer of undoped material on the insulation liner;
doping the undoped material located on one vertical sidewall of a word line trench and maintaining the undoped material located on the opposite vertical sidewall of a word line trench; and
etching the undoped material selectively to the doped material and removing the underlying insulation liner.

23. The method of claim 22, comprising using an angled implanting process for doping the undoped material on one vertical sidewall of a word line trench.

24. The method of claim 22, comprising maintaining the undoped material located on the floor of a word line trench undoped.

25. An integrated circuit comprising:
an array of diodes at least partially formed in a substrate for selecting one of a plurality of memory cells;
wherein a diode is coupled to a word line, the word line comprising a straight-lined portion and protrusions; and
wherein the diode comprises an active area located between two adjacent protrusions.
